(19) United States
(12) Patent Application Publication
(10) Pub. No.: US 2017/0336624 A1
(43) Pub. Date: Nov. 23, 2017

(54) ELECTROOPTICAL DEVICE, ELECTRONIC DEVICE, AND METHOD FOR MANUFACTURING ELECTROOPTICAL DEVICE

(71) Applicant: SEIKO EPSON CORPORATION, Tokyo (JP)

(72) Inventor: Masashi NAKAGAWA, Suwa-shi (JP)

(73) Assignee: SEIKO EPSON CORPORATION, Tokyo (JP)

(21) Appl. No.: 15/591,514

(22) Filed: May 10, 2017

(30) Foreign Application Priority Data
May 23, 2016 (JP) 2016-102174

(51) Int. Cl. G02B 26/08; B81C 1/00; B81B 3/00

(52) U.S. Cl. CPC G02B 26/0841; B81B 3/0048; B81C 1/00476; B81B 2203/0154; B81B 2201/042; B81B 2203/0361; B81C 2201/0108; B81B 2203/033

(57) ABSTRACT

An electrooptical device includes a first metal layer disposed spaced apart from a first surface of a substrate and including a mirror, which modulates light, and a mirror support post, which has a tubular shape and protrudes from the mirror toward the substrate. The first metal layer is formed by forming a metal layer on a surface of a sacrificial layer having an opening, patterning the metal layer, and removing the sacrificial layer. Thus, the mirror support post is formed so as to extend over the inner wall of the opening. Here, the mirror support post has a thickness of not less than 1.5 times the length of the mirror support post.

### BACKGROUND

### 1. Technical Field

The present invention relates to an electrooptical device including a mirror, an electronic device, and a method for manufacturing an electrooptical device.

### 2. Related Art

Examples of electronic devices that are known include a projection display device that modulates light from a light source using multiple mirrors (micromirrors) of an electrooptical device, called a digital micromirror device (DMD). In an electrooptical device used as such an electronic device, mirrors are disposed spaced apart from one surface of the substrate and supported by respective torsion hinges, disposed between the mirrors and the substrate, with mirror support posts interposed between the mirrors and the torsion hinge.

In a step of manufacturing an electrooptical device, a step of manufacturing mirrors includes forming of a sacrificial layer that covers torsion hinges, then forming, in the sacrificial layer, openings that reach the torsion hinges, and depositing a metal layer over the sacrificial layer. When the sacrificial layer is removed after the metal layer is patterned, portions of the metal layer covering the sacrificial layer form mirrors and portions of the metal layer covering the inner walls of the openings form tubular mirror support posts. When, however, a mirror support post is formed in the above-described method, a metal layer is deposited so as to have an overhang portion that protrudes from the opening edge of each opening. Thus, a portion of the metal layer covering the inner wall of each opening and hidden by the overhang portion forms a thin portion, at which the finished mirror support post has low strength. Thus, the mirror support post may be damaged after the corresponding mirror is caused to swing repeatedly.

To address this, another method is disclosed. In this method, a pillar-shaped post made of a resin pillar material is formed on each torsion hinge, and then a mirror is formed on the post. In another disclosed structure, a conductive layer is disposed so as to cover the upper surface and the outer peripheral surfaces of each pillar-shaped mirror support post to allow the mirrors and the torsion hinges to be electrically connected with one another (see JP A-8-227042).

However, as in the case of the structure described in JP A-8-227042, in the structure in which a pillar-shaped post made of a resin pillar material is disposed on a torsion hinge, the torsion hinge beats a heavier load. Moreover, when a conductive layer is disposed so as to cover the upper surface and the outer peripheral surfaces of each pillar-shaped mirror support post, the conductive layer partially overlaps the torsion hinge, so that the elasticity of the torsion hinge changes.

### SUMMARY

An advantage of some aspects of the invention is to provide an electrooptical device including a tubular mirror support post integrated with a mirror and having high strength, an electronic device including the electrooptical device, and a method for manufacturing the electrooptical device.

An electrooptical device according to an aspect of the invention made to solve the above-described problem includes a substrate, a first metal layer, a torsion hinge, a hinge support post, a first elevated address electrode, and a first electrode support post. The first metal layer is disposed spaced apart from a first surface of the substrate and includes a mirror, which modulates light, and a mirror support post, which has a tubular shape and protrudes from the mirror toward the substrate. The torsion hinge is disposed spaced apart from the first surface of the substrate between the first metal layer and the substrate. The torsion hinge supports the mirror with the mirror support post interposed therebetween. The hinge support post supports the torsion hinge between the torsion hinge and the substrate. The first elevated address electrode is located between the mirror and the substrate while being spaced apart from the mirror and the substrate. The first electrode support post supports the first elevated address electrode between the first elevated address electrode and the substrate. The mirror support post has a thickness of not less than 1.5 times a length of the mirror support post.

In an electrooptical device according to an aspect of the invention, the mirror support post has a thickness of not less than 1.5 times the length of the mirror support post. Thus, the mirror support post has a small aspect ratio (ratio of length of mirror support post to thickness of mirror support post). The mirror support post can thus have high strength. When the mirror support post is formed by forming a first metal layer over the surface of the sacrificial layer having an opening so as to cover the inner wall of the opening, the mirror support post is less likely to have a thin portion. Thus, the mirror support post can have high strength even when it has a tubular shape.

A method for manufacturing an electrooptical device according to an aspect of the invention includes forming a hinge support post and a torsion hinge on a first surface of a substrate, forming, after forming the hinge support post and the torsion hinge, a sacrificial layer on a surface of the torsion hinge opposite to a surface closer to the substrate, forming a metal layer on a surface of the sacrificial layer opposite to a surface closer to the substrate, patterning the metal layer to form a mirror, which modulates light, and a mirror support post, which has a tubular shape, and removing the sacrificial layer. The torsion hinge is supported at an end portion of the hinge support post opposite to an end portion closer to the substrate. The sacrificial layer has an opening that reaches the torsion hinge. The mirror overlaps the sacrificial layer. The mirror support post supports the mirror inside the opening. The opening has an opening diameter of not less than 1.5 times a depth of the opening.

With a method for manufacturing an electrooptical device according to an aspect of the invention, a mirror support post is formed by forming a metal layer over a surface of a sacrificial layer including an opening so as to cover an inner wall of the opening, the opening having an opening diameter of not less than 1.5 times the depth of the opening. The opening thus has a small aspect ratio (ratio of depth of opening to opening diameter of opening), so that the mirror support post is less likely to have a thin portion. The mirror support post can thus have high strength even when it has a tubular shape.

In an aspect of the invention, the mirror support post may be thinner than the hinge support post. In this aspect, a recess, if formed in the surface of the mirror attributable to the presence of the mirror support post, would be small. The reflectance properties of the mirror can thus be prevented from being reduced.

In an aspect of the invention, the mirror support post may be shorter than the hinge support post. In this aspect, the mirror support post can have high strength since the mirror support post is short.

In an aspect of the invention, an electrooptical device may include a second metal layer including the torsion hinge and the hinge support post.

In an aspect of the invention, an electrooptical device may include an elevated address electrode located between the mirror and the substrate while being spaced apart from the mirror and the substrate, and an electrode support post that supports the elevated address electrode between the elevated address electrode and the substrate. The elevated address electrode may be disposed in the same layer as the torsion hinge. The electrode support post may be disposed in the same layer as the hinge support post.

In an aspect of the invention, the hinge support post may be supported by the substrate.

In an aspect of the invention, an electrooptical device may include a hinge support layer disposed between the torsion hinge and the substrate, and a support post that supports the hinge support layer between the hinge support layer and the substrate. The hinge support post may be supported by the hinge support layer.

In an aspect of the invention, an electrooptical device may include a second metal layer, including the torsion hinge and the hinge support post, and a third metal layer, including the hinge support layer and the support post.

In an aspect the invention, an electrooptical device may include a first elevated address electrode, disposed in the same layer as either the torsion hinge or the hinge support layer, and a first electrode support post, supporting the first elevated address electrode between the first elevated address electrode and the substrate.

In an aspect of the invention, an electrooptical device may include a second elevated address electrode disposed in the same layer as the hinge support layer, and a second electrode support post disposed in the same layer as the support post, the second electrode support post supporting the second elevated address electrode between the second elevated address electrode and the substrate. The first elevated address electrode may be disposed in the same layer as the torsion hinge. The first electrode support post may be disposed in the same layer as the hinge support post. The first electrode support post may be supported by the second elevated address electrode.

In an aspect of the invention, the support post may be supported by the substrate.

In an aspect of the invention, the hinge support layer may include a spring chip with which the mirror comes into contact when the mirror swings so that the spring chip restricts a range within which the mirror swings. In this configuration, the mirror and the spring chip are spaced apart from each other to a large extent, so that the range within which the mirror swings can be extended.

In an aspect of the invention, the hinge support layer may be thicker than the torsion hinge.

An electrooptical device to which an aspect of the invention is applied may be included in various types of electronic device. When the electronic device is used as a projection display device, the electronic device includes a light source unit, which radiates light-source light to the mirror, and a projection optical system, which projects modulated light emitted from the electrooptical device.

### BRIEF DESCRIPTION OF THE DRAWINGS

The invention will be described with reference to the accompanying drawings, wherein like numbers reference like elements.

FIG. 1 illustrates an electronic device (projection display device) to which an aspect of the invention is applied.

FIG. 2 illustrates mirrors of an electrooptical device to which an aspect of the invention is applied.

FIG. 3 is an exploded perspective view of a main portion of an electrooptical device according to a first embodiment of the invention.

FIG. 4 illustrates movements of an electrooptical device to which an aspect of the invention is applied.

FIG. 5 is a sectional view of the electrooptical device according to the first embodiment of the invention taken along a torsion hinge.

FIG. 6 is a sectional view of steps of a method for manufacturing an electrooptical device according to the first embodiment of the invention.

FIG. 7 is a sectional view of steps of the method for manufacturing the electrooptical device according to the first embodiment of the invention.

FIG. 8 is a plan view of a layer formed through steps of manufacturing an electrooptical device according to the first embodiment of the invention.

FIG. 9 is a plan view of a layer formed through steps of manufacturing an electrooptical device according to the first embodiment of the invention.

FIG. 10 is an exploded perspective view of a main portion of an electrooptical device according to a third embodiment of the invention.

FIG. 11 is a sectional view of the electrooptical device according to the third embodiment of the invention taken along a torsion hinge.

FIG. 12 is a sectional view of steps of a method for manufacturing an electrooptical device according to the third embodiment of the invention.

FIG. 13 is a sectional view of steps of the method for manufacturing an electrooptical device according to the third embodiment of the invention.

FIG. 14 is a sectional view of steps of the method for manufacturing an electrooptical device according to the third embodiment of the invention.

FIG. 15 is an enlarged perspective view of a portion of an electrooptical device according to a fourth embodiment of the invention.

FIG. 16 is a plan view of part of the electrooptical device illustrated in FIG. 15.

FIG. 17 illustrates movements of the electrooptical device illustrated in FIG. 15.

### DESCRIPTION OF EXEMPLARY EMBODIMENTS

Now, embodiments of the invention are described with reference to the drawings. Layers and components are illustrated in different scales between different drawings that are referred to in the following description so that the layers or components are identifiable on each of the drawings. The number of mirrors or other components illustrated on the drawings as determined so that the mirrors or other components have a size identifiable on each drawing. However, a number of mirrors or components may be larger than the number of mirrors or components illustrated on the drawings.

### First Embodiment

### Entire Configuration of Electronic Device 1000

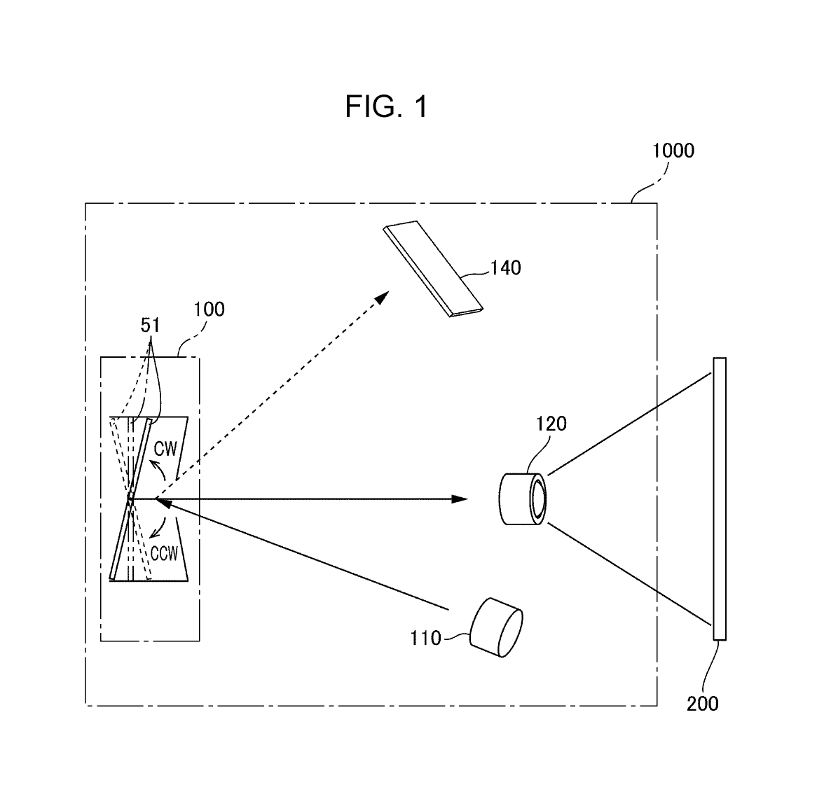

FIG. 1 illustrates an electronic device 1000 (projection display device) to which an aspect of the invention is applied. FIG. 1 illustrates only one of multiple mirrors 51 included in an electrooptical device 100. In FIG. 1, each mirror 51 is illustrated in a two-dot chain line when in a regular position, in a solid line when in a turn-on position, and in a dotted line when in a turn-off position.

The electronic device 1000 illustrated in FIG. 1 includes a light source unit 110 and an electrooptical device 100 that modulates light-source light emitted from the light source unit 110 in accordance with image information. The electronic device 1000 also includes a projection optical system 120, which projects light modulated by the electrooptical device 100 to an object 200, such as a wall surface or a screen, in the form of a projection image. The electronic device 1000 is thus formed as a projection display device. The light source unit 110 sequentially emits red light, green light, and blue light. The electrooptical device 100 sequentially modulates the red light, the green light, and the blue light and emits light of these colors to the projection optical system 120. The electrooptical device 100 is thus capable of displaying a color image.

An example of a configuration employable by the light source unit 110 is a configuration in which white light emitted from a light source is emitted to the electrooptical device 100 through a color filter (not illustrated). Alternatively, the light source unit 110 may have a configuration in which a light emitting device that emits red light, a light emitting device that emits green light, and a light emitting device that emits blue light are sequentially turned on to sequentially emit red light, green light, and blue light. In either case, the electrooptical device 100 modulates incident light in synchronization with time at which the light source unit 110 emits red light, green light, and blue light.

### Basic Configuration of Electrooptical Device 100

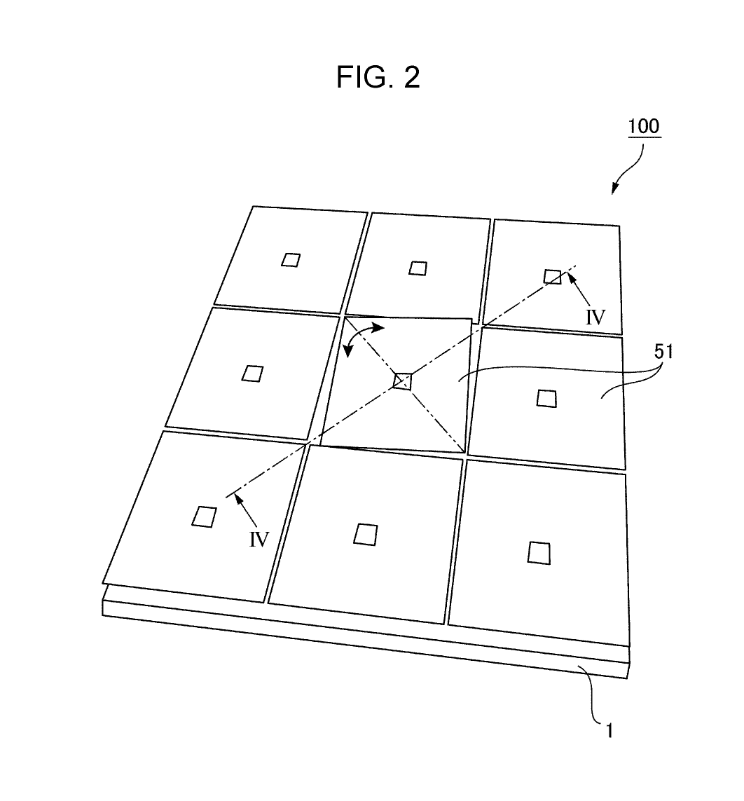

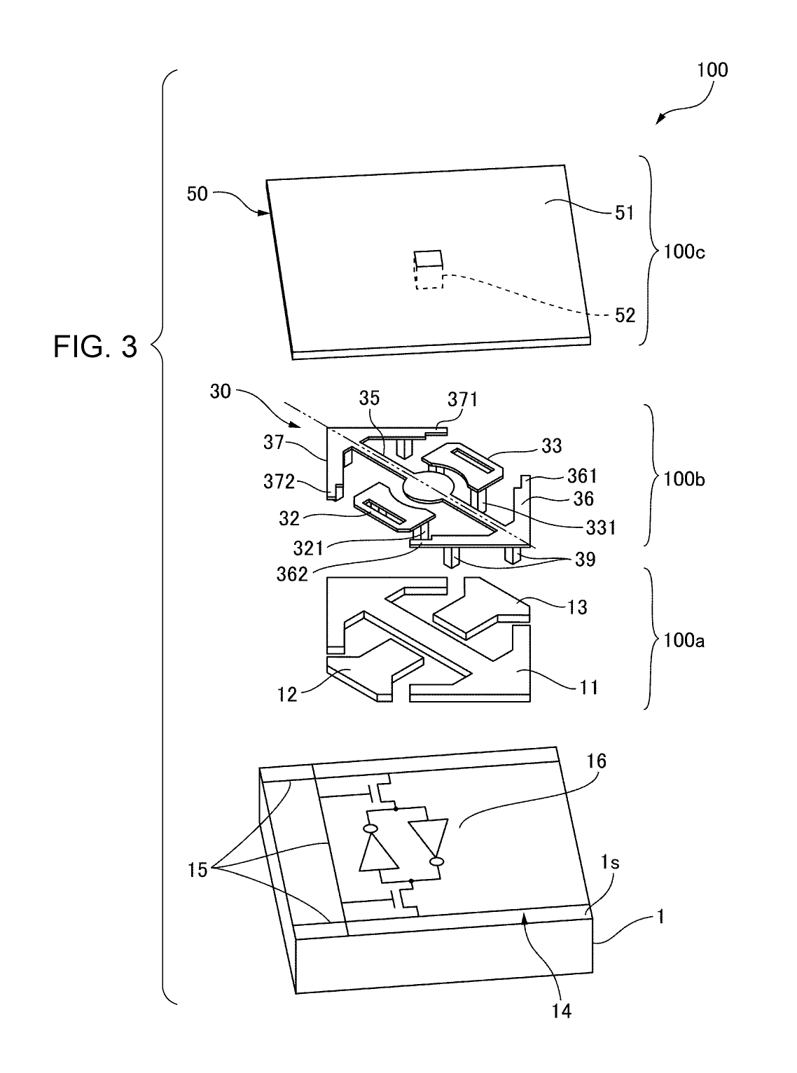

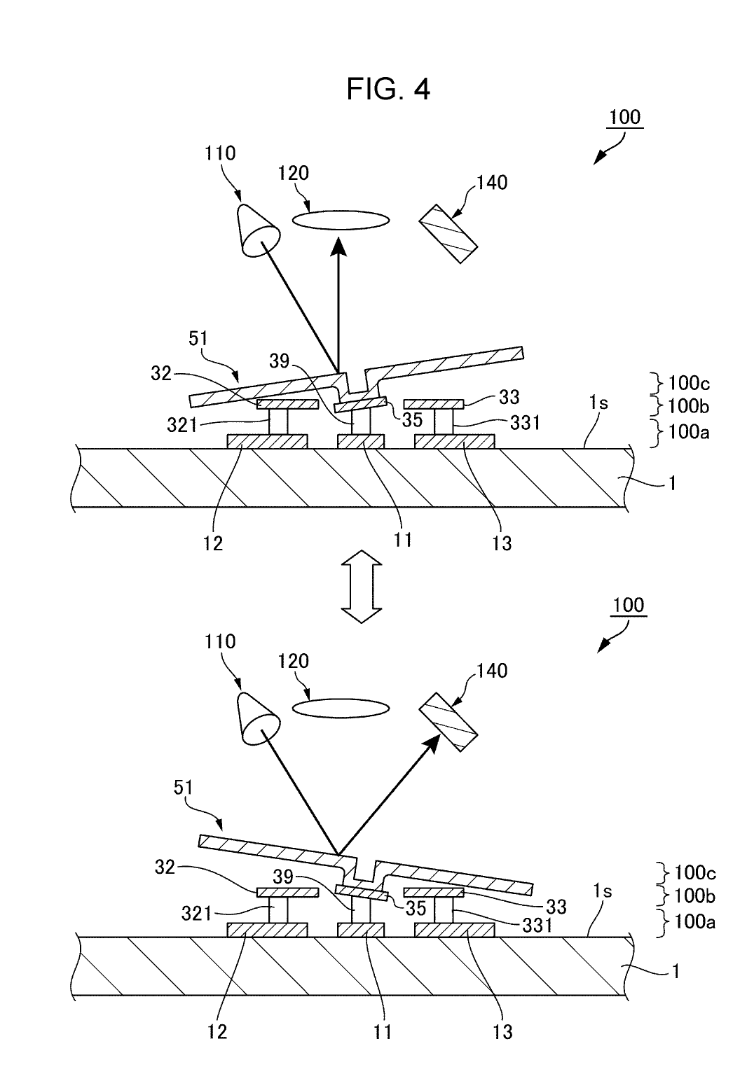

FIG. 2 illustrates mirrors 51 of the electrooptical device 100. FIG. 3 is an exploded perspective view of a main portion of the electrooptical device 100 according to the first embodiment of the invention. FIG. 4 illustrates movements of the electrooptical device 100 to which an aspect of the invention is applied. FIG. 4 schematically illustrates one mirror 51 in a state of being inclined to one side and a state of being inclined to the other side.

As illustrated in FIG. 2, FIG. 3, and FIG. 4, the electrooptical device 100 includes a substrate 1 and Multiple mirrors 51. The multiple mirrors 51 are arranged in a matrix so as to face a first surface 1s of the substrate 1 and spaced apart from the substrate 1. An example of the substrate 1 is a silicon substrate. Each mirror 51 is a micromirror having a surface whose side length is, for example, 10 to 30 μm. The mirrors 51 are arranged in, for example, a 600×800 array or a 1920×1080 array, where one mirror 51 corresponds to one pixel of an image (unit mirror portion 5).

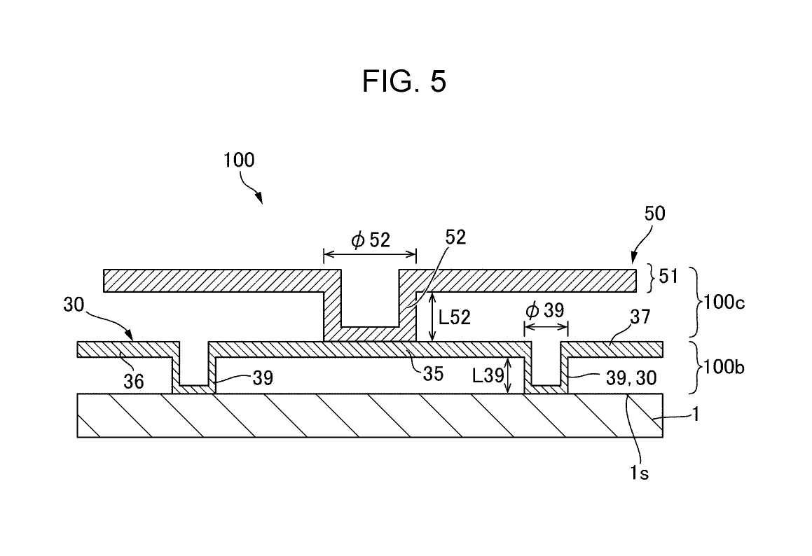

As illustrated in FIG. 3, FIG. 4, and FIG. 5, the surface of each mirror 51 forms a reflection surface made of a reflective metal layer such as aluminum. The electrooptical device 100 includes a first-level portion 100a, a second-level portion 100b, and a third-level portion 100c. The first-level portion 100a includes substrate bias electrodes 11 and substrate address electrodes 12 and 13 formed on the first surface is of the substrate 1. The second-level portion 100b includes elevated address electrodes 32 and 33 and torsion hinges 35. The third-level portion 100c includes the mirrors 51. In the first-level portion 100a, an address circuit 14 is formed on the substrate 1. The address circuit 14 includes a memory cell for selectively controlling movements of the corresponding mirror 51 and wires 15 including a word line and a bit line. The address circuit 14 has a circuit configuration similar to that of a random access memory (RAM) including a CMOS circuit 16.

The second-level portion 100b includes elevated address electrodes 32 and 33, torsion hinges 35, electrode support posts 321 and 331, and hinge support posts 39. The third-level portion 100c includes mirrors 51 and mirror support posts 52. The elevated address electrodes 32 and 33 are supported by the substrate 1 (substrate address electrodes 12 and 13) with the electrode support posts 321 and 331 interposed therebetween. The elevated address electrodes 32 and 33 are respectively electrically connected to the substrate address electrodes 12 and 13 with the electrode support posts 321 and 331 interposed therebetween. Thus, an address voltage is applied to the elevated address electrodes 32 and 33 from the substrate address electrodes 12 and 13 with the electrode support posts 321 and 331 interposed therebetween.

Each torsion hinge 35 has end portions 36 and 37, which extend two different directions. The end portions 36 and 37 of each torsion hinge 35 are supported by the substrate 1 (corresponding substrate bias electrode 11) with the hinge support posts 39 interposed therebetween. The end portions 36 and 37 of each torsion hinge 35 are electrically connected to the corresponding substrate bias electrode 11 with the hinge support posts 39 interposed therebetween. Each mirror 51 is supported by and electrically connected to the corresponding torsion hinge 35 with the corresponding mirror support post 52 interposed therebetween. Each mirror 51 is thus electrically connected to the corresponding substrate bias electrode 11 with the corresponding mirror support post 52, the corresponding torsion hinge 35, and the corresponding hinge support posts 39 interposed therebetween and receives a bias voltage from the substrate bias electrode 11. The end portions 36 and 37 of each torsion hinge 35 include spring chips 361, 362, 371, and 372, with which the mirror 51 comes into contact when the mirror 51 is inclined to prevent the mirror 51 and the elevated address electrode 32 or 33 from coming into contact with each other.

The substrate address electrodes 12 and 13 and the elevated address electrodes 32 and 33 form a driving electrode that produces electrostatic force between itself and the mirror 51 to drive the mirror 51 so as to incline the mirror 51. Specifically, each torsion hinge 35 is twisted when a driving voltage is applied to the substrate address electrodes 12 and 13 and the elevated address electrodes 32 and 33 and the mirror 51 is inclined, as illustrated in FIG. 4, so as to be attracted to the substrate address electrode 12 and the elevated address electrode 32 or to the substrate address electrode 13 and the elevated address electrode 33. Each torsion hinge 35 exerts its force of restoration with which the mirror 51 is returned to the position parallel to the substrate 1 when the application of the driving voltage to the substrate address electrodes 12 and 13 and the elevated address electrodes 32 and 33 is stopped and the force of attracting the mirror 51 is thus lost.

When, for example, each mirror 51 is inclined toward the substrate address electrode 12 and the elevated address electrode 32 in the electrooptical device 100, the mirror 51 enters an ON-state where the mirror 51 reflects light emitted from the light source unit 110 toward the projection optical system 120. When, on the other hand, each mirror 51 is inclined toward the substrate address electrode 13 and the elevated address electrode 33, the mirror 51 enters an OFF-state where the mirror 51 reflects light emitted from the light source unit 110 toward an optical absorptive device 140. When the mirror 52 is in the OFF-state, the mirror 51 does not reflect light to the projection optical system 120. Each of the multiple mirrors 51 is independently driven in the above-described manner. Light emitted from the light source unit 110 is modulated by the multiple mirrors 51 into image light, which is projected by the projection optical system 120 to display an image.

In some cases, a flat-shaped yoke opposing the substrate address electrodes 12 and 13 is disposed so as to be integrated with each torsion hinge 35. In such cases, the corresponding mirror 51 is driven by, besides electrostatic force produced between the mirror 51 and each of the elevated address electrodes 32 and 33, electrostatic force exerted between the yoke and each of the substrate address electrodes 12 and 13.

### Detailed Configuration of Electrooptical Device 100

FIG. 5 is a sectional view of the electrooptical device 100 according to the first embodiment of the invention taken along the torsion hinge 35. FIG. 5 only illustrates the second-level portion 100b and the third-level portion 100c of the electrooptical device 100 and does not include an illustration of the first-level portion 100a including the substrate bias electrode 11 and the substrate address electrodes 12 and 13. In FIG. 5, the layers and the components are illustrated in various different scales. The mirror support post 52 is enlarged further than other part.

As illustrated in FIG. 4 and FIG. 5, the electrooptical device 100 includes the mirror support posts each protruding from the corresponding mirror 51 toward the substrate 1, and each mirror support post 52 is continuous with the mirror 51 at its end opposite to the end closer to the substrate 1. Specifically, the mirror 51 and the mirror support post 52 are formed from an integrated unit of a first metal layer 50. In the first metal layer 50, the mirror support post 52 protrudes from the mirror 51 toward the substrate 1 and is supported by the torsion hinge 35.

The electrooptical device 100 includes the hinge support posts 39, each protruding from the corresponding torsion hinge 35 toward the substrate 1. Each of the hinge support posts 39 is continuous with the corresponding torsion hinge 35 at its end opposite to the end closer to the substrate 1. Specifically, each torsion hinge 35 and the corresponding hinge support posts 39 are formed from an integrated unit of a second metal layer 30. In the second metal layer 30, each hinge support post 39 protrudes from the corresponding torsion hinge 35 toward the substrate 1 and is supported by the substrate 1.

The electrooptical device 100 includes the electrode support posts 321 and 331, protruding from the respective elevated address electrodes 32 and 33 toward the substrate 1. The electrode support posts 321 and 331 are continuous with the respective elevated address electrodes 32 and 33 at their ends opposite to the ends closer to the substrate 1. In this embodiment, the elevated address electrodes 32 and 33 are formed in the same layer as the torsion hinge 35 and the electrode support posts 321 and 331 are formed in the same layer as the hinge support post 39. Specifically, the elevated address electrodes 32 and 33 and the electrode support posts 321 and 331 are formed in the same layer as the second metal layer 30.

In the electrooptical device 100 having the above-described configuration, the thickness φ52 of the mirror support post 52 is 0.8 μm and the length L52 of the mirror support post 52 is 0.4 μm. The thickness 39 of the hinge support post 39 is 1.0 μm and the length L39 of the hinge support post 39 is 1.3 μm. Thus, the thickness φ52 of the mirror support post 52 is twice the length L52 of the mirror support post 52, which is not smaller than 1.5 times the length L52 of the mirror support post 52. The thickness φ52 of the mirror support post 52 is smaller than the thickness φ39 of the hinge support post 39. The length L52 of the mirror support post 52 is shorter than the length L39 of the hinge support post 39.

### Method for Manufacturing Electrooptical Device

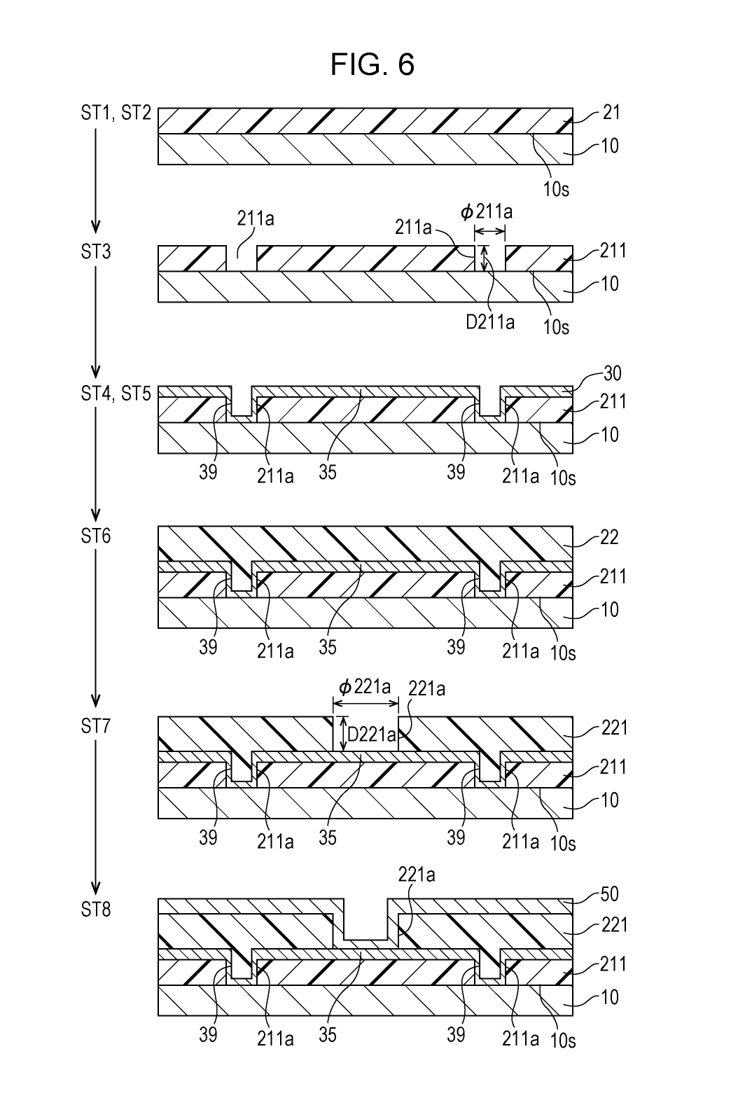

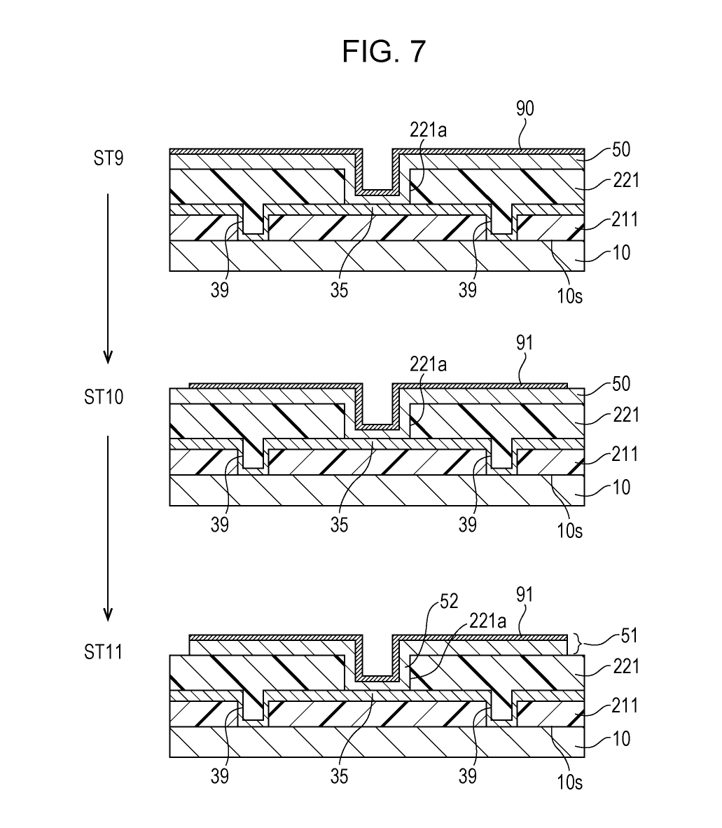

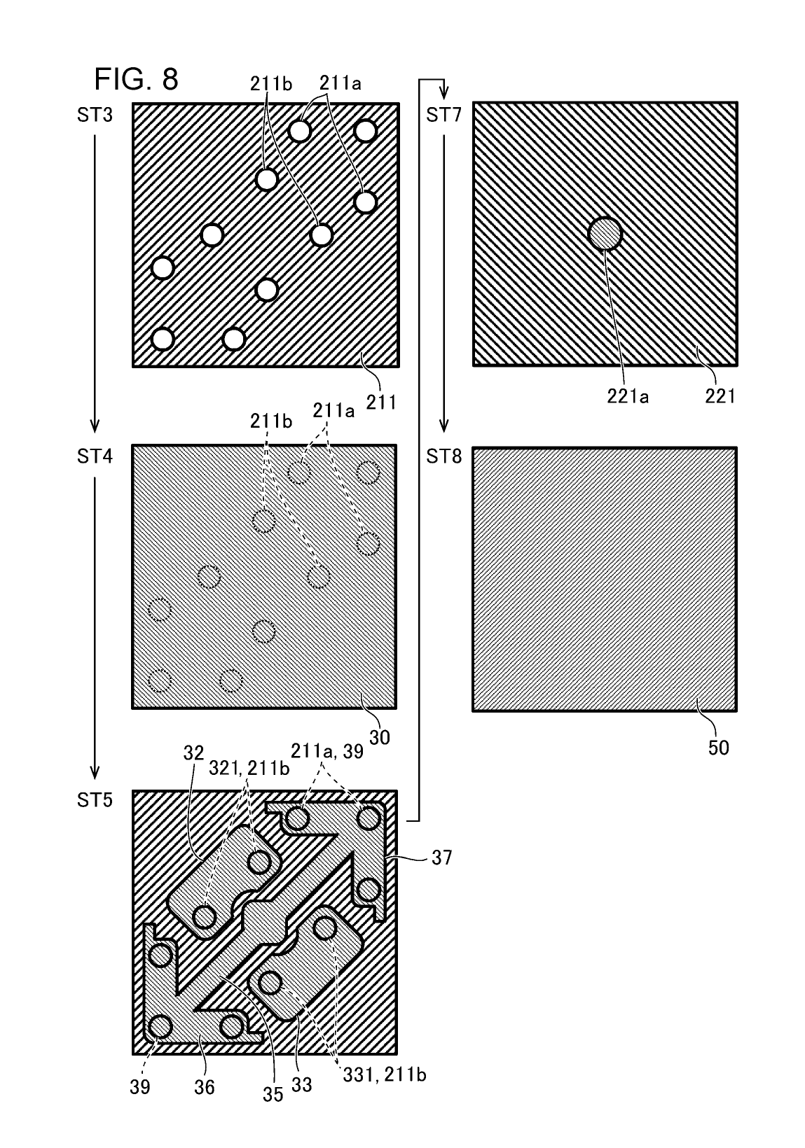

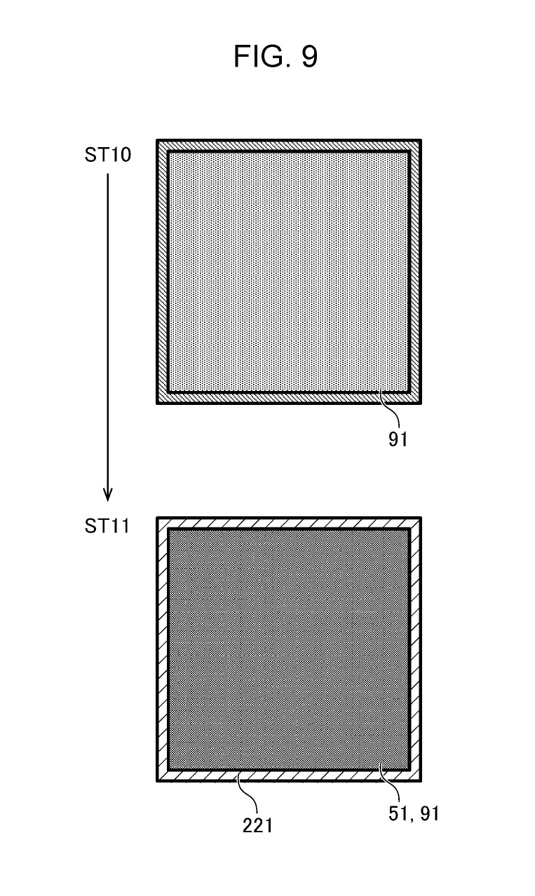

Referring to FIG. 6 to FIG. 9, among steps of manufacturing the electrooptical device 100 according to the first embodiment of the invention, steps of forming the torsion hinge 35, the mirror support post 52, and the mirror 51 are mainly described. FIG. 6 and. FIG. 7 are sectional views of steps included in a method for manufacturing the electrooptical device 100 according to the first embodiment of the invention. FIG. 8 and FIG. 9 are plan views of layers formed in the steps of manufacturing the electrooptical device 100 according to the first embodiment of the invention. FIG. 6 to FIG. 9 only illustrate, among multiple mirrors 51 of the electrooptical device 100, one mirror support post 52 and one torsion hinge 35 corresponding to one mirror 51. In the following description, FIG. 3 is appropriately referred to to describe the relationship between these components and the other components described above.

First, in step ST1 illustrated in FIG. 6, components such as the address circuit 14, the substrate bias electrode 11, and the substrate address electrodes 12 and 13, which are described above with reference to FIG. 3, are formed on a wafer 10 (substrate) formed of a silicon substrate.

Subsequently, in step ST2 illustrated in FIG. 6, a photosensitive resist layer 21 made of, for example, a positive organic photoresist, is formed over a first surface 10s of the wafer 10. Then, in step ST3 illustrated in FIG. 6, the photosensitive resist layer 21 is exposed to light and developed to form a fib sacrificial layer 211 having hinge-support-post receiving openings 211a. At this time in step ST3, electrode support-post receiving openings 211b for forming the electrode support posts 321 and 331 of the elevated address electrodes 32 and 33 are also formed in the first sacrificial layer 211, as illustrated in FIG. 8. These steps ST2 and ST3 are steps for forming the first sacrificial layer. The first sacrificial layer 211 has a thickness of, for example, 1.9 μm. The opening diameter φ211a of each hinge-support-post receiving opening 211a is, for example, approximately 1.0 μm and the depth D211a of the hinge-support-post receiving opening 211a is 1.9 μm.

Subsequently in step ST4 (step of forming a second metal layer) illustrated in FIG. 6, a second metal layer 30 is formed over the entirety of the surface of the first sacrificial layer 211 (surface opposite to the surface facing the wafer 10) (see step ST4 of FIG. 8). At the same time, the second metal layer 30 is formed over the inner walls and the bottom portions of the hinge-support-post receiving openings 211a and the electrode support-post receiving openings 211b. The second metal layer 30 is, for example, a single layer of an aluminum layer or a laminate layer of an aluminum layer and a titanium layer. The second metal layer 30 has a thickness of, for example, 0.06 μm.

Subsequently in step ST5 (step of patterning the second metal layer) illustrated in FIG. 6, the second metal layer 30 is patterned in the state where the surface of the second metal layer 30 (surface opposite to the surface facing the wafer 10) is covered with a resist mask, so that a portion of the second metal layer 30 left over the inner wall and the bottom portion of each hinge-support-post receiving opening 211a forms a tubular hinge support post 39 integrated with the torsion hinge 35. At the same time, as illustrated in FIG. 8, the elevated address electrodes 32 and 33 are respectively formed integrally with the tubular electrode support posts 321 and 331 at the inner walls and the bottom portions of the electrode support-post receiving openings 211b.

Subsequently in step ST6 illustrated in FIG. 6, a photosensitive resist layer 22 formed of a material such as a positive organic photoresist, is formed on the surface of the torsion hinge 35 opposite to the surface facing the wafer 10. Then, in step ST7 illustrated in FIG. 6, the photosensitive resist layer 22 is exposed to light and developed to form a second sacrificial layer 221 having a mirror-support-post receiving opening 221a (see step ST7 in FIG. 8). These steps ST6 and ST7 are steps of forming a second sacrificial layer (step of forming a sacrificial layer).

The second sacrificial layer 221 has a thickness (height) of, for example, 0.4 μm. The opening diameter φ221a of the mirror-support-post receiving opening 221a is, for example, 0.8 μm and the depth D221a of the mirror-support-post receiving opening 221a is 0.4 μm. Thus, the opening diameter φ221a of the mirror-support-post receiving opening 221a is twice the depth D221a of the mirror-support-post receiving opening 221a, which is not smaller than 1.5 times the depth D221a of the mirror-support-post receiving opening 221a. The mirror-support-post receiving opening 221a has a smaller opening diameter than each hinge-support-post receiving opening 211a and the mirror-support-post receiving opening 221a has a shallower depth than the hinge-support-post receiving opening 211a.

Subsequently in step ST8 (step of forming a first metal layer or step of forming a metal layer) illustrated in FIG. 6, the first metal layer 50 is formed on the surface of the second sacrificial layer 221 opposite to the surface facing the wafer 10 (see step ST8 of FIG. 8). The first metal layer 50 is, for example, a single layer of an aluminum layer or a laminate layer of an aluminum layer and a titanium layer. The first metal layer 50 has a thickness of, for example, 0.25 μm.

Subsequently in step ST9 illustrated in FIG. 7, an inorganic film 90 such as a silicon oxide film (SiO₂) is formed by, for example, plasma-enhanced chemical vapor deposition (PECVD). Then, in step ST10 illustrated in FIG. 7, an inorganic film 90 is patterned in the state where the surface of the inorganic film 90 (surface opposite to the surface facing the wafer 10) is covered with a resist mask to form an etch-stop layer 91 having the same flat surface shape as the mirror 51 (see step ST10 of FIG. 9). Thereafter, the resist mask is removed.

Subsequently in step ST11 illustrated in FIG. 7, the first metal layer 50 is patterned using the etch-stop layer 91 as a mask to form the mirror 51 (see step ST11 of FIG. 9). Thus, a portion of the first metal layer 50 that covers the second sacrificial layer 221 forms the mirror 51 and a portion of the first metal layer 50 that covers the inner wall and the bottom portion of the mirror-support-post receiving opening 221a forms a tubular mirror support post 52. These steps ST9, ST10, and ST11 are steps of patterning the first metal layer 50.

Thereafter, the wafer 10 is divided into multiple substrates 1 each having a single-product size. Then, the substrates 1 are subjected to plasma etching or other processes to remove the first sacrificial layer 211 and the second sacrificial layer 221 (step of removing sacrificial layers). At the same time, the etch-stop layer 91 is also removed. Thus, the electrooptical device 100 illustrated in FIG. 5 is obtained.

### Main Effects of Embodiment

As described above, in the electrooptical device 100 according to this embodiment, the thickness φ52 of the mirror support post 52 is not smaller than 1.5 times the length L52 of the mirror support post 52. Thus, the mirror support post 52 has a small aspect ratio (ratio of length L52 of mirror support post 52 to thickness φ52 of mirror support post. Thus, the mirror support post 52 has high strength. In the method for manufacturing the electrooptical device 100 according to this embodiment, the first metal layer 50 is formed over the surface of the sacrificial layer 221 having the mirror-support-post receiving opening 221a and the mirror support post 52 is formed so as to cover the inner wall of the mirror-support-post receiving opening 221a. Here, the opening diameter φ221a of the mirror-support-post receiving opening 221a is not smaller than 1.5 times the depth D221a of the mirror-support-post receiving opening 221a. The mirror-support-post receiving opening 221a thus has a small aspect ratio (ratio of depth D221a of mirror-support-post receiving opening 221a to opening diameter 221a of mirror-support-post receiving opening 221a), so that the mirror support post 52 is less likely to have a thin portion. If the mirror support post 52 has a thin portion, the thin portion can retain a thickness of at least approximately ⅕ to 1/10 the thickness of the mirror 51. Thus, the mirror support post 52 can have high strength even when it has a tubular shape.

When, on the other hand, the thickness φ52 of the mirror support post 52 is less than 1.5 times the length L52 of the mirror support post 52, the mirror-support-post receiving opening 221a has a large aspect ratio. Thus, the first metal layer 50, when deposited, has an overhang portion that extends inward from the opening edge of the mirror-support-post receiving opening 221a. A portion of the first metal layer 50 covering the inner wall of the mirror-support-post receiving opening 221a and hidden by this overhang portion is formed into a thin portion, at which the finished mirror support post 52 has low strength. Thus, in this embodiment, the thickness φ52 of the mirror support post 52 is determined to be not smaller than 1.5 times the length L52 of the mirror support post 52.

In this embodiment, the mirror support post 52 has a small aspect ratio, so that the center of gravity of the mirror 51 is located adjacent to the torsion hinge 35. Thus, the torsion hinge 35 bears a small stress when the mirror 51 swings, so that the torsion hinge 35 is less likely to have damages or other defects.

The mirror support post 52 is thinner than the hinge support post 39. Thus, a recess, if formed in the surface of the mirror 51 attributable to the presence of the mirror support post 52, would be small. The reflectance properties of the mirror 51 are thus prevented from being reduced. In addition, the mirror support post 52 is shorter than the hinge support post 39 or other components. Since the mirror support post 52 is short, the mirror support post 52 can have high strength.

### Second Embodiment

The basic configuration of a second embodiment is similar to that of the first embodiment. The second embodiment is different from the first embodiment in terms of the dimensions of components such as the mirror support post 52 and the mirror-support-post receiving opening 221a. Thus, the second embodiment is described with reference to FIG. 5 and FIG. 6, which are referred to when the first embodiment is described.

In the second embodiment, the thickness of the first sacrificial layer 211 (depth D211a of each hinge-support-post receiving opening 211a) is 0.5 μm and the opening diameter φ211a of each hinge-support-post receiving opening 211a is 0.8 μm. Thus, the length L39 of the hinge support post 39 is 0.5 μm and the thickness φ39 of the hinge support post 39 is 0.8 μm. The thickness of the second sacrificial layer 221 (depth D221a of the mirror-support-post receiving opening 221a) is 0.3 μm and the opening diameter φ221a of the mirror-support-post receiving opening 221a is 0.5 μm. The length L52 of the mirror support post 52 is 0.3 μm. The thickness φ52 of the mirror support post 52 is 0.5 μm.

Since the thickness 52 of the mirror support post 52 is not smaller than 1.5 times the length L52 of the mirror support post 52, the mirror support post 52 has a small aspect ratio (ratio of length L52 of mirror support post 52 to thickness φ52 of mirror support post 52). Specifically, the opening diameter φ221a of the mirror-support-post receiving opening 221a is not smaller than 1.5 times the depth D221a of the mirror-support-post receiving opening 221a. The second embodiment thus has the similar effects as the first embodiment, including an effect of enhancing the strength of the mirror support post 52 having a tubular shape.

The mirror support post 52 according to the second embodiment is the same as that of first embodiment in terms that it is thinner and shorter than the hinge support post 39.

In the second embodiment, the thickness of the first metal layer 50 is 0.15 μm and the thickness of the second metal layer 30 is 0.03 μm.

### Third Embodiment

### Configuration of Electrooptical Device 100

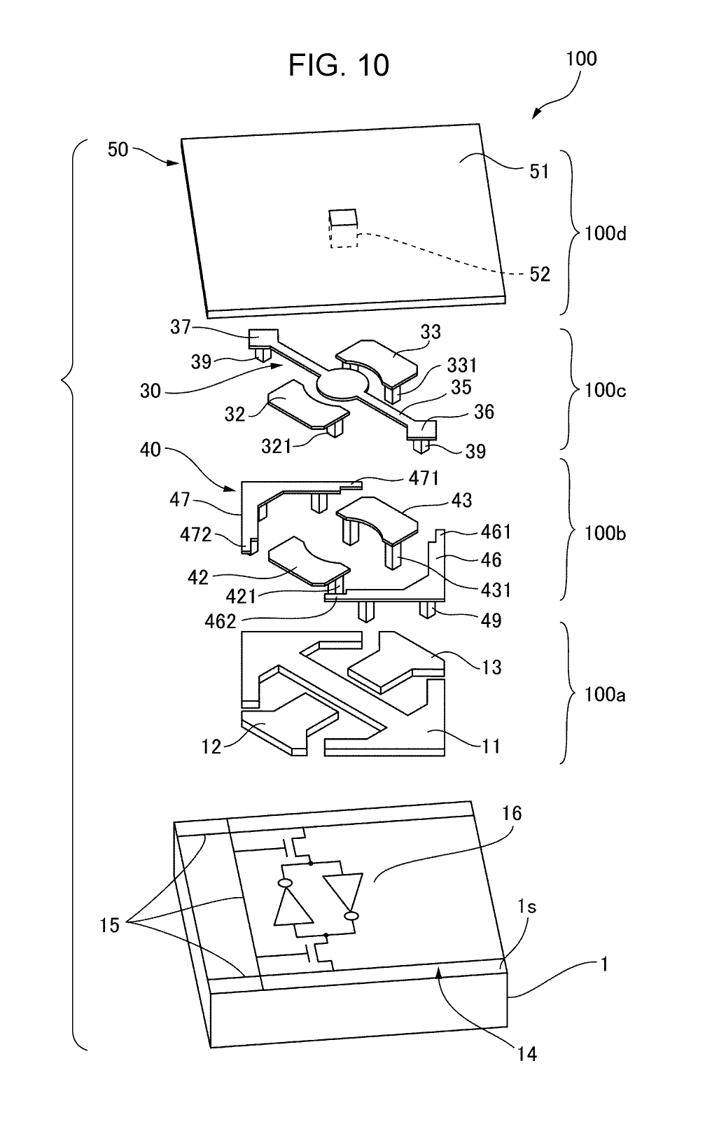

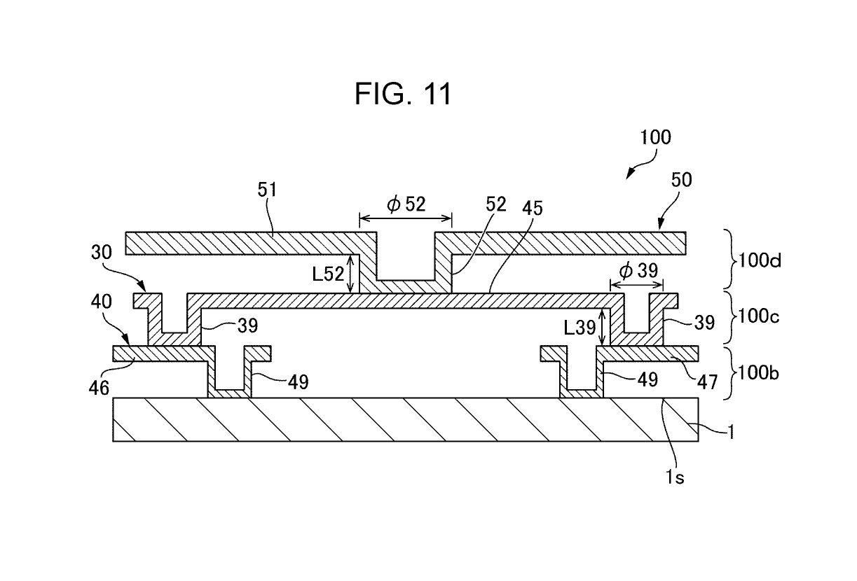

FIG. 10 is an exploded perspective view of a main portion of an electrooptical device 100 according to a third embodiment of the invention. FIG. 11 is a sectional view of the electrooptical device 100 according to the third embodiment of the invention taken along the torsion hinge 35. FIG. 11 only illustrates a second-level portion 100b, a third-level portion 100c, and a fourth-level portion 100d of the electrooptical device 100 and does not illustrate a first-level portion 100a including the substrate bias electrode 11 and the substrate address electrodes 12 and 13. In FIG. 11, layers and components are illustrated in different scales and the mirror support post 52 is illustrated in a larger scale than other portions. Since the basic configuration of the third embodiment is similar to that of the first embodiment, the same components are denoted with the same reference numerals.

As illustrated in FIG. 10 and FIG. 11, the electrooptical device 100 according to the third embodiment includes portions of four different levels (the first-level portion 100a, the second-level portion 100b, the second-level portion 100c, and the fourth-level portion 100d). The first-level portion 100a includes the substrate bias electrode 11 and the substrate address electrodes 12 and 13 formed on the first surface is of the substrate 1. The second-level portion 100b includes hinge support layers 46 and 47 and elevated address electrodes 42 and 43 (second elevated address electrode). The third-level portion 100c includes the torsion hinge 35 and the elevated address electrodes 32 and 33 (first elevated address electrode). The fourth-level portion 100c includes the mirror 51.

In the second-level portion 100b, the hinge support layers 46 and 47 are respectively supported by the substrate 1 (substrate bias electrode 11) with support posts 49 interposed therebetween and electrically connected to the substrate bias electrode 11 with the support posts 49 interposed therebetween. In the second-level portion 100b, the elevated address electrodes 42 and 43 are supported by the substrate 1 (substrate address electrodes 12 and 13) with electrode support posts 421 and 431 (second electrode support posts) interposed therebetween and electrically connected to the substrate address electrodes 12 and 13 with the electrode support posts 421 and 431 interposed therebetween.

In the third-level portion 100c, the end portions 36 and 37 of the hinge 35 are respectively supported by the hinge support layers 46 and 47 with the hinge support posts 39 interposed therebetween and electrically connected to the hinge support layers 46 and 47 with the hinge support posts 39 interposed therebetween. In the third-level portion 100c, the elevated address electrodes 32 and 33 (first elevated address electrodes) are respectively supported by the elevated address electrodes 42 and 43 with the electrode support posts 321 and 331 (first electrode support posts) interposed therebetween and electrically connected to the elevated address electrodes 42 and 43 with the electrode support posts 321 and 331 interposed therebetween. The elevated address electrodes 32 and 33 thus respectively receive address voltages from the substrate address electrodes 12 and 13 through the electrode support posts 321 and 331, the elevated address electrodes 42 and 43, and the electrode support posts 421 and 431.

In the fourth-level portion 100d, the mirror 51 is supported by the torsion hinge 35 with the mirror support post 52 interposed therebetween and electrically connected to the torsion hinge 35 with the mirror support post 52 interposed therebetween. Thus, the mirror 51 is electrically connected to the substrate bias electrode 11 with the mirror support post 52, the torsion hinge 35, the hinge support posts 39, the hinge support layers 46 and 47, and the support posts 49 interposed therebetween and receives a bias voltage from the substrate bias electrode 11. The hinge support layers 46 and 47 include, at their end portions, spring chips 461, 462, 471, and 472, with which the mirror 51 comes into contact when the mirror 51 is inclined to prevent the mirror 51 and the elevated address electrode 32 or 33 or another component from coming into contact with each other.

In this embodiment, an end portion of the mirror support post 52 opposite to the end portion closer to the substrate 1 is continuous with the mirror 51. Specifically, the mirror 51 and the mirror support post 52 are formed from a single unit of the first metal layer 50. In the first metal layer 50, the mirror support post 52 protrudes from the mirror 51 toward the substrate 1 and is supported by the torsion. hinge 35.

An end portion of each hinge support post 39 opposite to an end portion closer to the substrate 1 is continuous with the torsion hinge 35. Specifically, the torsion hinge 35 and the hinge support posts 39 are formed from a single unit of the second metal layer 30. In the second metal layer 30, each hinge support post 39 protrudes from the torsion hinge 35 toward the substrate 1 and is supported by the substrate 1. End portions of the electrode support posts 321 and 331 opposite to the end portions closer to the substrate 1 are respectively continuous with the elevated address electrodes 32 and 33. In this embodiment, the elevated address electrodes 32 and 33 are formed in the same layer as the torsion hinge 35. The electrode support posts 321 and 331 are formed in the same layer as the hinge support posts 39. Specifically, the elevated address electrodes 32 and 33 and the electrode support posts 321 and 331 are formed in the same layer as the second metal layer 30.

End portions of the support posts 49 opposite to the end portions closer to the substrate 1 are continuous with the hinge support layers 46 and 47. Specifically, the hinge support layers 46 and 47 and the support posts 49 are formed from a single unit of a third metal layer 40. In the third metal layer 40, each support post 49 protrudes toward the substrate 1 from the hinge support layer 46 or 47 and is supported by the substrate 1. Here, the hinge support layers 46 and 47 are thicker than the torsion hinge 35. In this embodiment, the hinge support layers 46 and 47 have a thickness of 0.25 μm and the torsion hinge 35 has a thickness of 0.06 μm. End portions of the electrode support posts 421 and 431 opposite to the end portions closer to the substrate 1 are respectively continuous with the elevated address electrodes 42 and 43. In this embodiment, the elevated address electrodes 42 and 43 are formed in the same layer as the hinge support layers 46 and 47. The electrode support posts 421 and 431 are formed in the same layer as the support posts 49. Specifically, the elevated address electrodes 42 and 43 and the electrode support posts 421 and 431 are formed in the same layer as the third metal layer 40.

In the electrooptical device 100 having this configuration, the thickness 52 of the mirror support post 52 is 0.5 μm and the length L52 of the mirror support post 52 is 0.25 μm. The thickness φ39 of the hinge support post 39 is 0.6 μm and the length L of the hinge support post 39 is 0.3 μm. Thus, the thickness φ52 of the mirror support post 52 is twice the length L52 of the mirror support post 52, which is not smaller than 1.5 times the length L52 of the mirror support post 52. The mirror support post 52 is thinner and shorter than the hinge support post 39.

### Method for Manufacturing Electrooptical Device

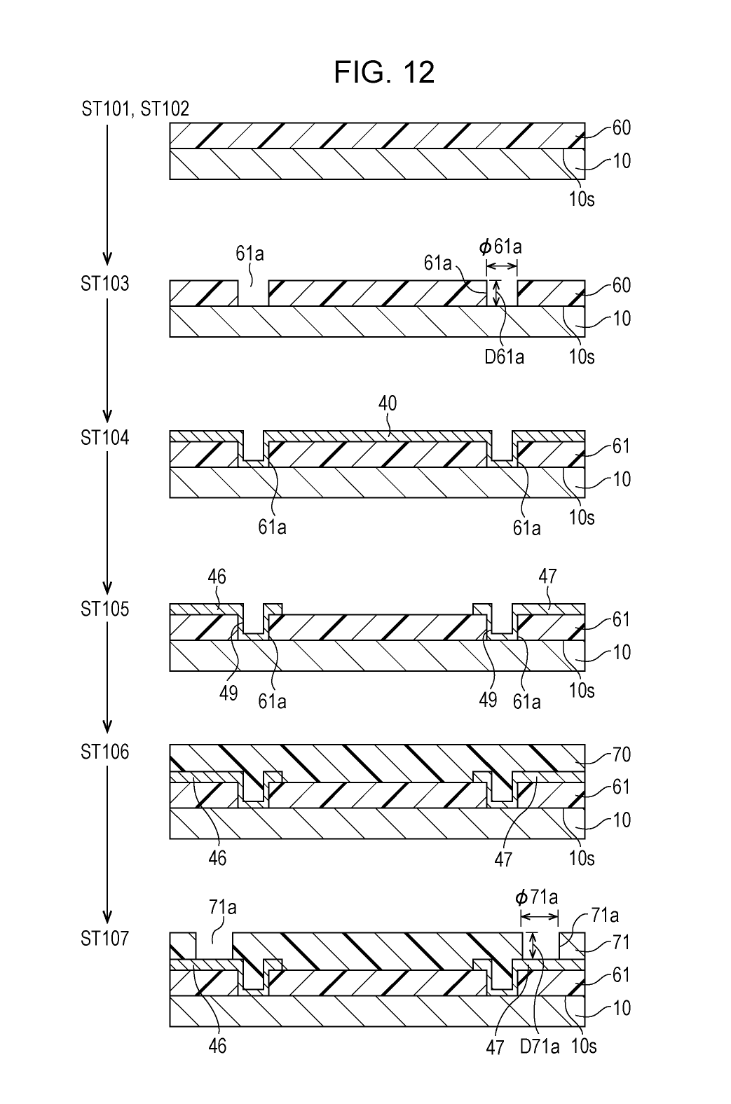

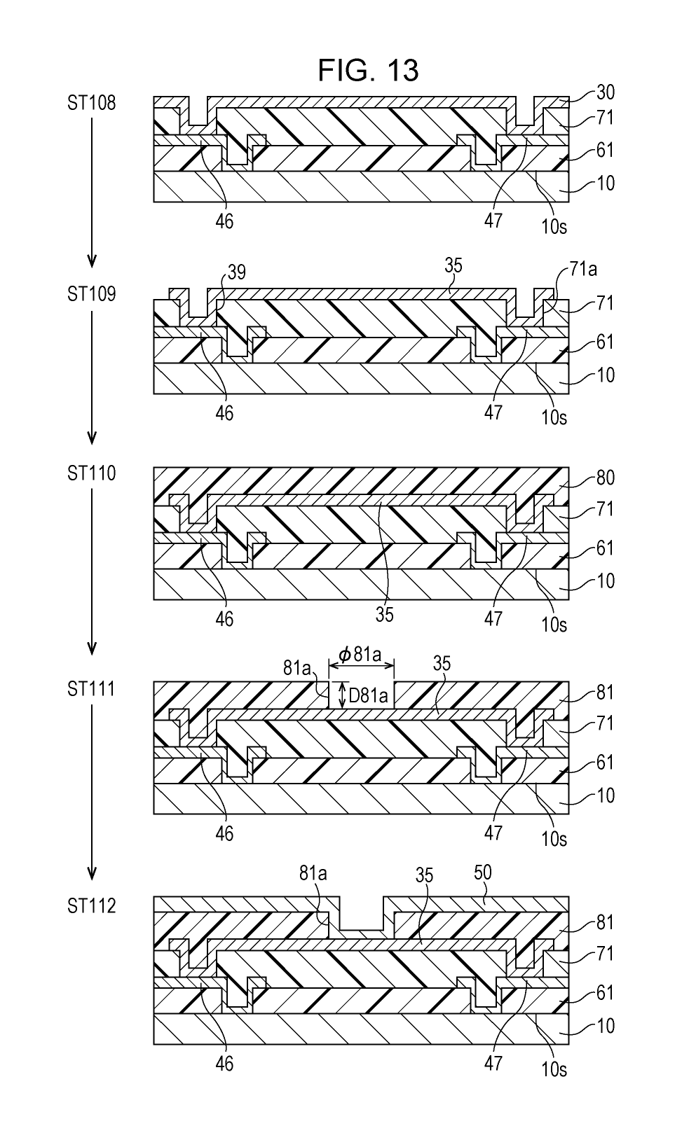

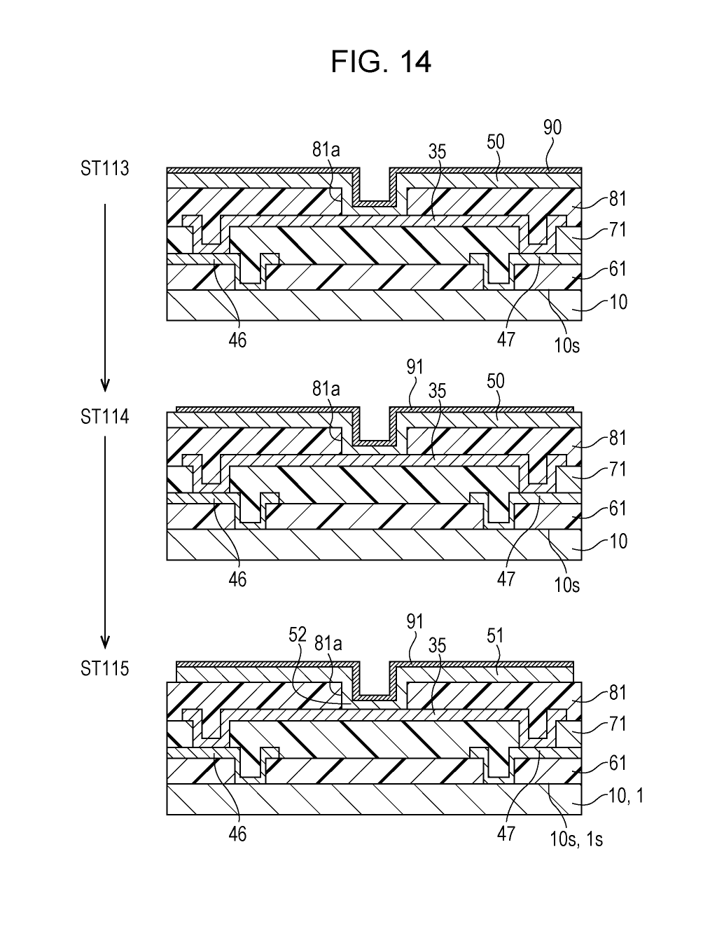

Referring now to FIG. 12, FIG. 13, and FIG. 14, steps of forming the torsion hinge 35, the mirror support post 52, and the mirror 51 are mainly described among steps of manufacturing the electrooptical device 100 according to the third embodiment of the invention. FIG. 12, FIG. 13, and FIG. 14 are sectional views of steps included in a method for manufacturing the electrooptical device 100 according to the third embodiment of the invention.

Firstly, in step ST101 illustrated in FIG. 12, components such as the address circuit 14, the substrate bias electrode 11, and the substrate address electrodes 12 and 13, which are described with reference to FIG. 3, are disposed on a wafer 10 (substrate) formed of a silicon substrate.

Subsequently, in step ST102 illustrated in FIG. 12, a photosensitive resist layer 60 formed of, for example, a positive organic photoresist, is formed over the first surface 10s of the wafer 10. Then, in step ST103 illustrated in FIG. 12, the photosensitive resist layer 60 is exposed to light and developed to form a first sacrificial layer 61 having support-post receiving openings 61a. At the same time, electrode support-post receiving openings for forming the electrode support posts 421 and 431 of the elevated address electrodes 42 and 43 are also formed in the first sacrificial layer 61. These steps ST102 and ST103 are steps of forming a first sacrificial layer. The first sacrificial layer 61 has a thickness of, for example, 0.5 μm. The opening diameter φ61a of the support-post receiving opening 61a is, for example, approximately 0.6 μm and the depth D61a of the support-post receiving opening 61a is 0.5 μm.

Subsequently in step ST104 illustrated in FIG. 12 (step for forming a third metal layer), the third metal layer 40 is formed over the entirety of the surface of the first sacrificial layer 61 (surface opposite to the surface facing the wafer 10). At the same time, the third metal layer 40 is also formed over the inner wall and the bottom portion of each of the support-post receiving openings 61a and the electrode support-post receiving openings. The third metal layer 40 is, for example, a single film of an aluminum layer or a laminate film of an aluminum layer and a titanium layer. The third metal layer 40 has a thickness of, for example, 0.25 μm.

Subsequently in step ST105 illustrated in FIG. 12 (step of patterning a second metal layer), the third metal layer 40 is patterned while the surface of the third metal layer 40 (surface opposite to the surface facing the wafer 10) is covered with a resist mask. Thus, the portions of the third metal layer 40 left over the inner wall and the bottom portion of each support-post receiving opening 61a form the tubular support posts 49 integrated with the hinge support layers 46 and 47. Concurrently, the elevated address electrodes 42 and 43 are also formed and the tubular electrode support posts 421 and 431 are formed on the inner walls and the bottom portions of the electrode support-post receiving openings.

Subsequently in step ST106 illustrated in FIG. 12, a photosensitive resist layer 70 (sacrificial layer) formed of a material such as a positive organic photoresist is formed over the surface of the first sacrificial layer 61 (surface opposite to the surface facing the wafer 10). Then, in step ST107 illustrated in FIG. 12, the photosensitive resist layer 70 is exposed to light and developed to form a second sacrificial layer 71 having hinge-support-post receiving openings 71a. At the same time, electrode support-post receiving openings for forming the electrode support posts 321 and 331 of the elevated address electrodes 32 and 33 are also formed in the second sacrificial layer 71. These steps ST106 and ST107 are steps for forming a second sacrificial layer. The second sacrificial layer 71 has a thickness of, for example, 0.3 μm. The opening diameter φ71a of each hinge-support-post receiving opening 71a is, for example, approximately 0.6 μm and the depth D71a of the hinge-support-post receiving opening 71a is 0.3 μm.

Subsequently in step ST108 illustrated in FIG. 13 (step of forming a second metal layer), the second metal layer 30 is formed over the entirety of the surface of the second sacrificial layer 71 (surface opposite to the surface facing the wafer 10). At the same time, the second metal layer 30 is also formed over the inner walls and the bottom portions of the hinge-support-post receiving openings 71a and electrode support-post receiving openings. The second metal layer 30 is, for example, a single film of an aluminum layer or a laminate film of an aluminum layer and a titanium layer. The second metal layer 30 has a thickness of, for example, 0.06 μm.

Subsequently in step ST109 illustrated in FIG. 13 (step of patterning a second metal layer), the second metal layer 30 is patterned while the surface of the second metal layer 30 (surface opposite to the surface facing the wafer 10) is covered with a resist mask. Thus, the portions of the second metal layer 30 left over the inner walls and the bottom portions of the hinge-support-post receiving openings 71a form the tubular hinge support posts 39 integrated with the torsion hinge 35. At the same time, the elevated address electrodes 32 and 33 are also formed on the inner walls and the bottom portions of the electrode support-post receiving openings so as to be integrated with the tubular electrode support posts 321 and 331.

Subsequently in step ST110 illustrated in FIG. 13, a photosensitive resist layer 80 formed of a material such as a positive organic photoresist is formed on the surface of the torsion hinge 35 opposite to the surface facing the wafer 10. Then, in step ST111 illustrated in FIG. 13, the photosensitive resist layer 80 is exposed to light and developed to form a third sacrificial layer 81 having a mirror-support-post receiving opening 81a. These steps ST110 and ST111 are steps of forming a third sacrificial layer (sacrificial layer forming step).

The third sacrificial layer 81 has a thickness (height) of, for example, 0.25 μm. The opening diameter φ81a of the mirror-support-post receiving opening 81a is, for example, 0.5 μm and the depth D81a of the mirror-support-post receiving opening 81a is 0.25 μm. The opening diameter φ81a of the mirror-support-post receiving opening 81a is twice the depth D81a of the mirror-support-post receiving opening 81a, which is not less than 1.5 times the depth D81a of the mirror-support-post receiving opening 81a. The mirror-support-post receiving opening 81a has a smaller opening diameter than the hinge-support-post receiving opening 71a and is shallower than the hinge-support-post receiving opening 71a.

Subsequently in step ST112 illustrated in FIG. 13 (step of forming a first metal layer or step of forming a metal layer), the first metal layer 50 is formed on the surface of the third sacrificial layer 81 opposite to the surface facing the wafer 10. The first metal layer 50 is, for example, a single film of an aluminum layer and a laminate film of an aluminum layer and a titanium layer. The first metal layer 50 has a thickness of, for example, 0.15 μm.

Subsequently in step ST113 illustrated in FIG. 14, an inorganic film 90, such as a silicon oxide film (SiO₂), is formed by, for example, PECVD. Then, in step ST114 illustrated in FIG. 14, the inorganic film 90 is patterned while the surface of the inorganic film 90 (surface opposite to the surface facing the wafer 10) is covered with a resist mask to form an etch-stop layer 91 having the same flat surface shape as the mirror 51. Thereafter, the resist mask is removed.

Subsequently in step ST115 illustrated in FIG. 14, the first metal layer 50 is patterned using the etch-stop layer 91 as a mask to form a mirror 51. A portion of the first metal layer 50 covering the third sacrificial layer 81 thus forms the mirror 51 and a portion of the first metal layer 50 covering the inner wall and the bottom portion of the mirror-support-post receiving opening 81a thus forms the tubular mirror support post 52. These steps ST112, ST113, ST114, and ST115 are steps of patterning the first metal layer 50.

Then, the wafer 10 is divided into multiple substrates 1 of a single-product size. Then, the substrates 1 are subjected to plasma etching or other processes to remove the first sacrificial layer 61, the second sacrificial layer 71, and the third sacrificial layer 81 (step of removing sacrificial layers). At the same time, the etch-stop layer 91 is removed. Thus, the electrooptical device 100 illustrated in FIG. 10 and FIG. 11 is obtained.

### Main Effects of Embodiment

As described above, in the electrooptical device 100 according to this embodiment, the thickness φ52 of the mirror support post 52 is not less than 1.5 times the length L52 of the mirror support post 52. Thus the mirror support post 52 has a small aspect ratio (ratio of length L52 of mirror support post 52 to thickness 52 of mirror support post 52), The mirror support post 52 can thus has high strength. In addition, in the method for manufacturing the electrooptical device 100 according to the embodiment, the first metal layer 50 is formed over the surface of the sacrificial layer 221 having a mirror-support-post receiving opening 221a and the mirror support post 52 is formed over the inner wall of the mirror-support-post receiving opening 221a. Here, the opening diameter 221a of the mirror-support-post receiving opening 221a is not less than 1.5 times the depth D221a of the mirror-support-post receiving opening 221a. Thus, the mirror-support-post receiving opening 221a has a small aspect ratio (ratio of depth D221a of mirror-support-post receiving opening 221a to opening diameter φ221a of mirror-support-post receiving opening 221a), so that the mirror support post 52 is less likely to have a thin portion. Thus, a thin portion of the mirror support post 52, if formed, can have a thickness of at least approximately ⅕ to 1/10 the thickness of the mirror 51. Thus, the third embodiment can have effects similar to those obtained in the first embodiment including an enhancement of the strength of the mirror support post 52 having a tubular shape.

In this embodiment, the hinge support layers 46 and 47 include spring chips 461, 462, 471, and 472. Thus, the mirror 51 and each of the spring chips 461, 462, 471, and 472 are spaced apart from each other to a large extent. The range over which the mirror 51 swings can thus be extended.

### Fourth Embodiment

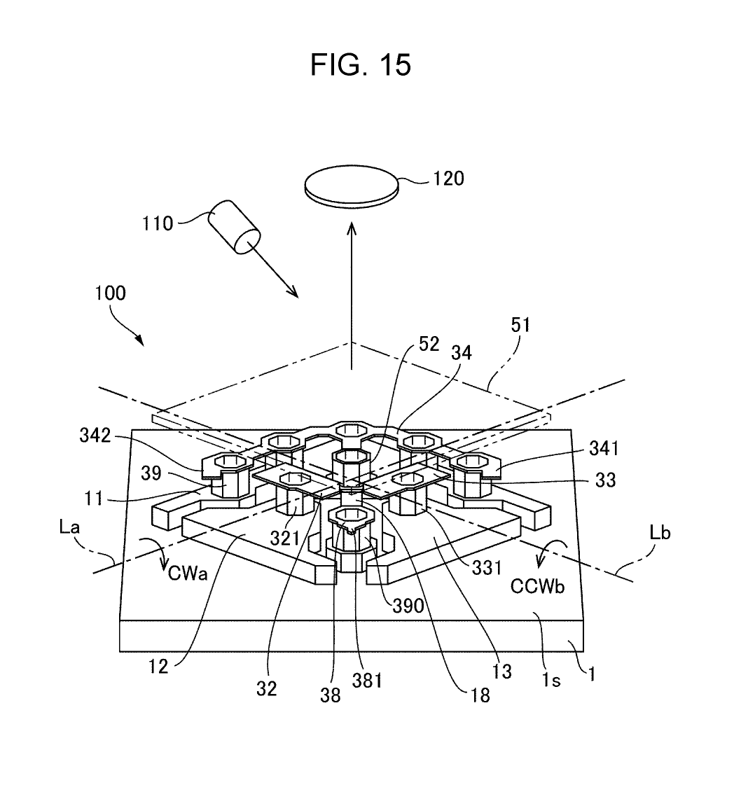

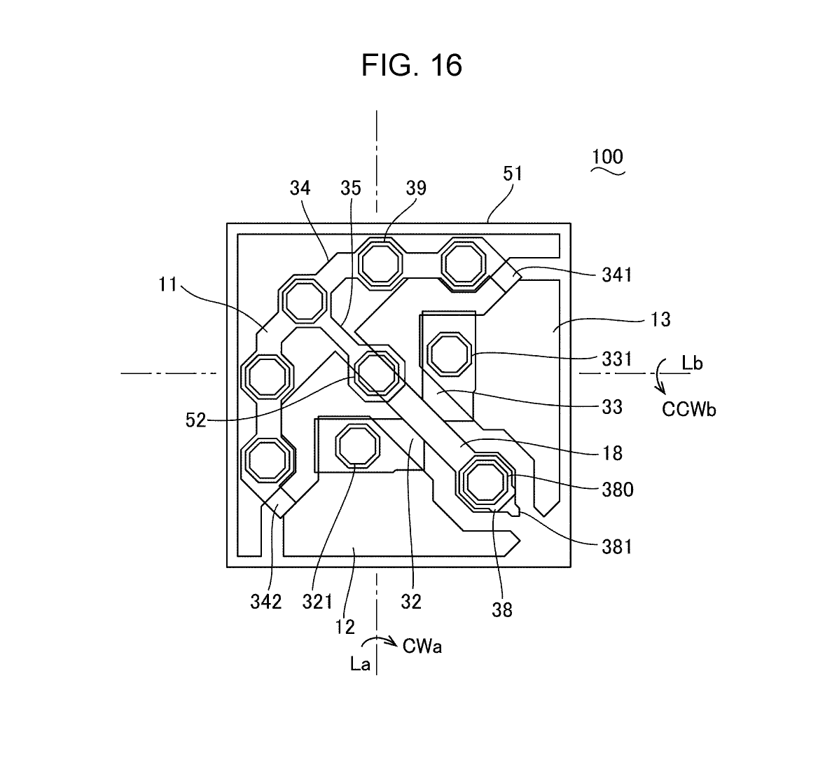

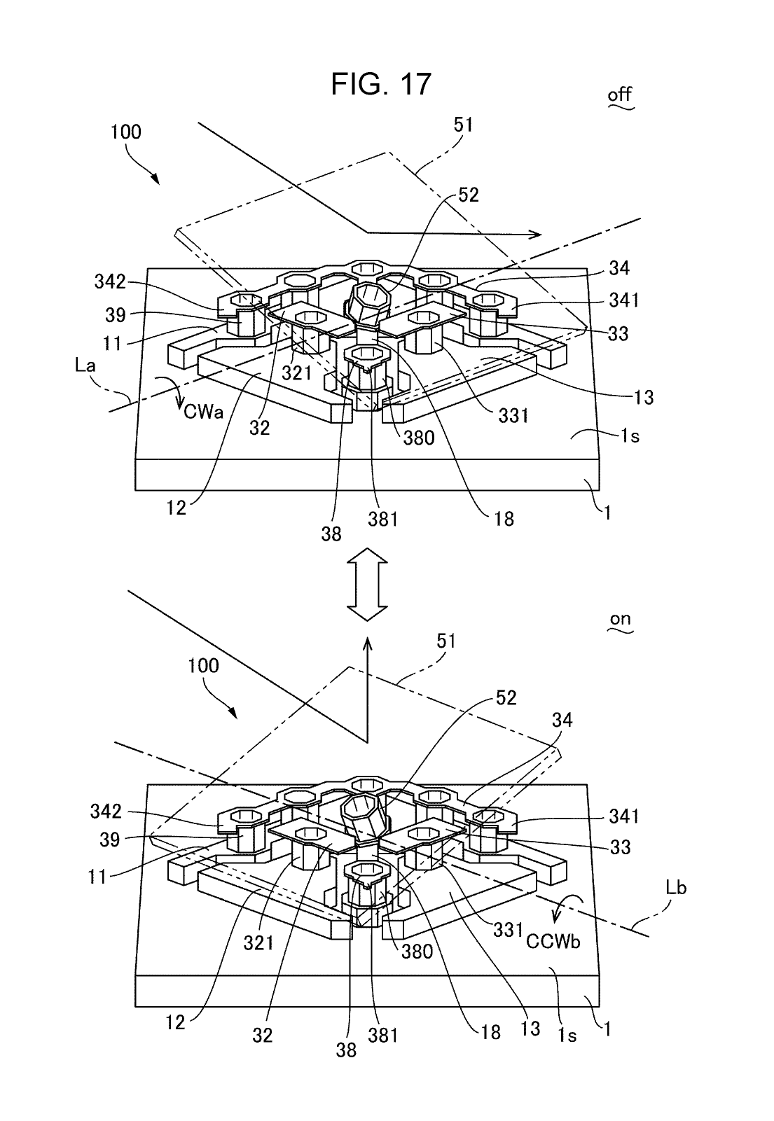

FIG. 15 is an enlarged perspective view of a portion of an electrooptical device 100 according to a fourth embodiment of the invention. FIG. 15 shows the electrooptical device 100 in a regular position. FIG. 16 is a plan view of a portion of the electrooptical device 100 illustrated in FIG. 15. FIG. 17 illustrates movements of the electrooptical device 100 illustrated in FIG. 15, where the mirror 51 is inclined in a first direction CWa around a first axis La to be in a turn-off position and the mirror 51 is inclined in a first direction CCWb around a second axis Lb to be in a turn-on position. In FIG. 15 and FIG. 17, the mirror 51 is drawn with two-dot chain lines.

In the electrooptical device 100 according to each of the first, second, and third embodiments, the mirror 51 is caused to swing around a single axis L. In the fourth embodiment, however, the mirror 51 is swingable around the first axis La and the second axis Lb, as described below with reference to FIG. 15, FIG. 16, and FIG. 17. The first axis La extends so as to overlap the mirror 51 when viewed in a plan and the second axis Lb extends so as to overlap the mirror 51 when viewed in a plan and perpendicular to the first axis La. As illustrated in FIG. 17, the mirror 51 according to this embodiment takes a turn-off position as a result of swinging in a first direction CWa around the first axis La and takes a turn-on position as a result of swinging in a first direction CCWb around the second axis Lb.

More specifically, as illustrated in FIG. 15 and FIG. 16, the electrooptical device 100 includes a substrate bias electrode 11, a torsion hinge 35, and elevated address electrodes 32 and 33 that are located between the mirror 51 and the substrate 1 so as to overlap the mirror 51 when viewed in a plan. In this embodiment, the substrate bias electrode 11 extends over the first surface 1s of the substrate 1 so as to be parallel to the first axis La and the second axis Lb. The torsion hinge 35 includes a hinge arm 34 extending along the substrate bias electrode 11. The hinge arm 34 is supported by the substrate bias electrode 11 with the hinge support posts 39 interposed therebetween. The hinge 35 protrudes from a bent portion of the hinge arm 34 in a direction that crosses the first axis La and the second axis Lb. The mirror 51 is supported at the end portion of the torsion hinge 35 with the mirror support post 52 interposed therebetween. The mirror 51 is thus supported by the torsion hinge 35 so as to be swingable around the first axis La and the second axis Lb. The substrate bias electrode 11 is capable of applying a bias voltage to the mirror 51 with the hinge support posts 39, the hinge arm 34, the torsion hinge 35, and the mirror support post 52 interposed therebetween.

A center bias electrode 18 extends from the substrate bias electrode 11 along the hinge 35. An electrode 38 disposed in the same layer as the hinge arm 34 is supported at the end portion of the center bias electrode 18 with an electrode post 380 interposed therebetween. The hinge arm 34 and the electrode 38 include spring chips 341, 342, and 381 with which the mirror 51 comes into contact when it is inclined.

In this embodiment, the elevated address electrode 32 is disposed on one side of the first axis La when viewed in a plan and supported by the substrate address electrode 12 with the electrode support post 321 interposed therebetween. The elevated address electrode 33 is disposed on one side of the second axis Lb when viewed in a plan and supported by the substrate address electrode 13 with the electrode support post 331 interposed therebetween. Thus, the mirror 51 is rendered swingable in the first direction CWa around the first axis La and swingable in the first direction CCWb around the second axis Lb by controlling address voltages applied to the elevated address electrodes 32 and 33.

The electrooptical device 100 having the above-described configuration is manufactured in the method similar to that of the first embodiment and other embodiments. The mirror support post 52, when having a thickness of not less than 1.5 times its length, can thus have high strength.

### Other Embodiments

In the embodiments described above, the mirror support post 52 can have high strength when it has a thickness of not less than 1.5 times its length, such as twice its length. Here, the thickness of the mirror support post 52 not less than 1.5 times its length does not have an upper limit as long as the mirror support post 52 can support the torsion hinge 35. If the mirror support post 52 has a thickness of not less than 2.5 times its length, the torsion hinge 35 can have sufficiently high properties such as elasticity or strength.

This application claims priority to Japan Patent Application No. 2016-102174 filed Mar. 23, 2016, the entire disclosures of which are hereby incorporated by reference in their entireties.

What is claimed is:

1. An electrooptical device, comprising:
a substrate;
a first metal layer disposed spaced apart from a first surface of the substrate and including a mirror, which modulates light, and a mirror support post, which has a tubular shape and protrudes from the mirror toward the substrate;
a torsion hinge disposed spaced apart from the first surface of the substrate between the first metal layer and the substrate, the torsion hinge supporting the mirror with the mirror support post interposed therebetween; and
a hinge support post supporting the torsion hinge between the torsion hinge and the substrate,
wherein the mirror support post has a thickness of not less than 1.5 times a length of the mirror support post.

2. The electrooptical device according to claim 1, wherein the mirror support post is thinner than the hinge support post.

3. The electrooptical device according to claim 1, wherein the mirror support post is shorter than the hinge support post.

4. The electrooptical device according to claim 1, further comprising a second metal layer including the torsion hinge and the hinge support post.

4. electrooptical device according to claim 4, further comprising:
an elevated address electrode located between the mirror and the substrate while being spaced apart from the mirror and the substrate; and
an electrode support post that supports the elevated address electrode between the elevated address electrode and the substrate,
wherein the elevated address electrode is disposed in the same layer as the torsion hinge, and
wherein the electrode support post is disposed in the same layer as the hinge support post.

6. The electrooptical device according to claim 1, wherein the hinge support post is supported by the substrate.

7. The electrooptical device according to claim 4, further comprising:
a hinge support layer disposed between the torsion hinge and the substrate; and
a support post that supports the hinge support layer between the hinge support layer and the substrate,
wherein the hinge support post supported by the hinge support layer.

8. The electrooptical device according to claim 7, further comprising:
a second metal layer including the torsion hinge and the hinge support post; and
a third metal layer including the hinge support layer and the support post.

9. The electrooptical device according to claim 7, further comprising:
a first elevated address electrode disposed in the same layer as either the torsion hinge or the hinge support layer; and
a first electrode support post that supports the first elevated address electrode between the first elevated address electrode and the substrate.

10. The electrooptical device according to claim 9, further comprising:
a second elevated address electrode disposed in the same layer as the hinge support layer; and
a second electrode support post disposed in the same layer as the support post, the second electrode support post supporting the second elevated address electrode between the second elevated address electrode and the substrate,
wherein the first elevated address electrode is disposed in the same layer as the torsion hinge,
wherein the first electrode support post is disposed in the same layer as the hinge support post, and
wherein the first electrode support post is supported by the second elevated address electrode.

11. The electrooptical device according to claim 7, wherein the support post is supported by the substrate.

12. The electrooptical device according to claim 7, wherein the hinge support layer includes a spring chip with which the mirror comes into contact when the mirror swings so that the spring chip restricts a range within which the mirror swings.

13. The electrooptical device according to claim 7, wherein the hinge support layer is thicker than the torsion hinge.

14. An electric device, comprising:
the electrooptical device according to claim 1;
a light source unit that radiates light-source light to the mirror; and
a projection optical system that projects modulated light emitted from the electrooptical device.

15. A method for manufacturing an electrooptical device, the method comprising:
forming a hinge support post and a torsion hinge on a first surface of a substrate, the torsion hinge being supported at an end portion of the hinge support post opposite to an end portion closer to the substrate;
forming, after forming the hinge support post and the torsion hinge, a sacrificial layer on a surface of the torsion hinge opposite to a surface closer to the substrate, the sacrificial layer having an opening that reaches the torsion hinge;
forming a metal layer on a surface of the sacrificial layer opposite to a surface closer to the substrate;
patterning the metal layer to form a mirror, which modulates light and overlaps the sacrificial layer, and a mirror support post, which has a tubular shape and supports the mirror inside the opening; and
removing the sacrificial layer,
wherein the opening has an opening diameter of not less than 1.5 times a depth of the opening.
